(19) United States
(12) Patent Application Publication
(10) Pub. No.: US 2011/0234329 A1
(43) Pub. Date: Sep. 29, 2011

(54) PACKAGE MARKING METHOD, PACKAGE, PIEZOELECTRIC VIBRATOR, OSCILLATOR, ELECTRONIC DEVICE, AND RADIO-CONTROLLED TIMEPIECE

(76) Inventor: Junya Fukuda, Chiba-shi (JP)

(21) Appl. No.: 13/069,850

(22) Filed: Mar. 23, 2011

(30) Foreign Application Priority Data
Mar. 26, 2010 (JP) 2010-073333
Oct. 20, 2010 (JP) 2010-235594

(51) Int. Cl. H03B 1/00; B32B 37/02; B32B 38/04; B32B 38/00; H01L 41/053; H01L 41/08; H01L 41/22; H05K 5/06

(52) U.S. Cl. 331/156; 156/272.8; 156/250; 310/344; 174/50.5

(57) ABSTRACT

Provided are a package marking method capable of printing a clean marking without impairing the reliability, a package manufactured by the method, a piezoelectric vibrator, and an oscillator, an electronic device, and a radio-controlled timepiece having the piezoelectric vibrator. A package marking method for printing a marking on the surface of a lid substrate formed of a glass includes a thin film forming step of forming a thin film on the surface of the lid substrate and a marking step of printing a marking on the surface of the lid substrate by irradiating the thin film formed by the thin film forming step with a laser beam to remove the thin film.

### RELATED APPLICATIONS

This application claims priority under 35 U.S.C. §119 to Japanese Patent Application Nos. 2010-073333 filed on Mar. 26, 2010 and 2010-235594 filed on Oct. 20, 2010, the entire contents of which are hereby incorporated by reference.

### BACKGROUND OF THE INVENTION

1. Field of the Invention

The present invention relates to a package marking method, a package, a piezoelectric vibrator, and an oscillator, an electronic device, and a radio-controlled timepiece each having the piezoelectric vibrator.

2. Background Art

In many cases, a piezoelectric vibrator utilizing a crystal or the like has been used, for example, in cellular phones and portable information terminals as the time source, the timing source of a control signal, a reference signal source, and the like. As the piezoelectric vibrator of this type, there is known a piezoelectric vibrator in which a piezoelectric vibrating reed, which is an electronic component, is vacuum-sealed in a package in which a cavity (sealed space) is formed. The package has a structure in which a pair of glass substrates is superimposed and directly bonded with a recess portion formed in one of the pair of glass substrates, whereby the recess portion functions as a cavity.

As a means for printing a marking on the surface of the glass substrate, a means for printing a marking using an ink jet printer, an ink stamp, or the like can be considered. However, the size of a marking is limited in a small component like the piezoelectric vibrator, and only a small number of characters can be printed as a marking. Therefore, a method of printing a marking on the surface of the glass substrate by irradiating and etching the surface of the glass substrate with a laser beam is known (for example, see JP-A-10-101379).

However, when the related art technique is used for a package in which an electronic component such as the piezoelectric vibrator is sealed therein, and a laser beam that passes through the glass substrate is used, the laser beam may have an influence on the electronic component.

On the other hand, the use of a laser beam of which the absorption ratio to the glass substrate is 100% can eliminate the influence on the electronic component. However, when the marking is printed by etching the surface of the glass substrate, the reliability of the package may decrease due to the occurrence of cracks or the like, and it is difficult to print a clean marking.

### SUMMARY OF THE INVENTION

The present invention has been made in view of the above problems, and an object of the present invention is to provide a package marking method capable of printing a clean marking without impairing the reliability, a package, a piezoelectric vibrator, and an oscillator, an electronic device, and a radio-controlled timepiece having the piezoelectric vibrator.

According to an aspect of the present invention, there is provided a package marking method for printing a marking on the surface of a glass of a package which includes: a first substrate and a second substrate which are bonded to each other and in which at least a part of the surface of at least one of the first and second substrate is formed of a glass; and a cavity formed between the first and second substrates and configured to be capable of sealing an electronic component, the method including: a thin film forming step of forming a thin film on the surface of the glass; and a marking step of printing a marking on the surface of the glass by irradiating the thin film formed by the thin film forming step with a laser beam to remove the thin film.

With this configuration, it is possible to print a marking on the surface without etching the surface of the glass. Therefore, it is possible to prevent the influence of the laser beam on the electronic component and to provide a package having high reliability.

Moreover, since the marking is printed by removing the thin film formed on the surface of the glass, it is possible to print a clean marking as compared to the case of etching the surface of the glass and to prevent the occurrence of cracks.

In the package marking method, it is preferable that the laser beam is in a wavelength region in which an absorption ratio thereof to the glass is 100%.

With this configuration, since the laser beam is reliably prevented from passing through the glass, it is possible to provide a package having higher reliability.

In the package marking method, it is preferable that the wavelength λ of the laser beam is set so as to satisfy a relation of λ≧7.5 μm.

With this configuration, it is possible to prevent the occurrence of cracks or the like in the glass.

Here, the wavelength region of the laser beam of which the absorption ratio to the glass is 100% generally includes a short wavelength region where the wavelength is several nm and a long wavelength region where the wavelength is several μm. Since the energy of the laser beam in the short wavelength region increases as the wavelength decreases, there is a possibility that cracks or the like occur in the glass. Therefore, by using a laser beam having a long wavelength, specifically a laser beam of which the wavelength λ, satisfies a relation of λ≧7.5 μm, 100% of the laser beam is absorbed in the glass, and the occurrence of cracks or the like in the glass can be prevented.

In the package marking method, it is preferable that the thickness T of the thin film is set so as to satisfy a relation of 1000 Å≦T≦3000 Å, and a CO₂ laser is used as the laser beam.

With this configuration, it is possible to reliably remove the thin film using the CO₂ laser and to print a clean marking.

Here, if the thickness T of the thin film is larger than 3000 Å, there is a possibility that it is unable to remove the thin film completely and to print a clean marking. Therefore, by setting the thickness T of the thin film so as to satisfy a relation of 1000 Å≦T≦3000 Å, it is possible to reliably print a clean marking.

In the package marking method, it is preferable that the output P of the laser beam is set so as to satisfy a relation of 4.5 W≦P≦6 W.

With this configuration, it is possible to reliably prevent the occurrence of cracks in the glass while reliably removing the thin film.

In the package marking method, it is preferable that the thin film is a film containing Si as a main component thereof.

With this configuration, a portion of the surface of the glass in which the thin film is removed can be made distinctive. That is, since Si absorbs a laser beam and has a colorant, the portion in which the thin film is removed can be clearly distinguished from the portion in which the thin film is not removed. Therefore, the portion of the surface of the glass in which the thin film is removed is made distinctive, and the marking can be clearly seen.

Moreover, since Si has high resistance to corrosion and high insulating properties, it is possible to increase the reliability of the package.

In the package marking method, it is preferable that the method includes, before the thin film forming step, a bonding step of anodically bonding a bonding material formed on one of the first and second substrates to the other substrate, and in the thin film forming step, the thin film is formed so as to cover the bonding material which is exposed to the outside from the gap between the first and second substrates.

With this configuration, it is possible to prevent the corrosion of the bonding material.

In the package marking method, it is preferable that in the thin film forming step, the package is disposed in a recess portion of a thin film forming jig, and the thin film is formed in a state in which the bonding material is exposed to the outside while accommodating outer electrodes of the package in the recess portion.

With this configuration, it is possible to cover the bonding material with the thin film while preventing the short-circuiting of the outer electrodes.

In the package marking method, it is preferable that in the thin film forming step, a plurality of packages is disposed in a plurality of recess portions of a thin film forming jig, and the thin film is formed in a state where each of the plurality of packages is separated from each other.

With this configuration, since the thin film can be formed on the side surfaces of the package, it is possible to reliably cover the bonding material with the thin film.

According to another aspect of the present invention, there is provided a package including: a first substrate and a second substrate which are bonded to each other and in which at least a part of the surface of at least one of the first and second substrate is formed of a glass; and a cavity formed between the first and second substrates and configured to be capable of sealing an electronic component, in which a thin film is formed on the surface of the glass, and a marking is printed on the surface of the glass by irradiating the thin film with a laser beam to remove the thin film.

With this configuration, it is possible to provide a package in which a clean marking is printed without impairing the reliability.

According to a further aspect of the present invention, there is provided a piezoelectric vibrator in which a piezoelectric vibrating reed is airtightly sealed in the cavity of the package according to the above aspect of the present invention.

With this configuration, it is possible to prevent the influence of the laser beam on the piezoelectric vibrating reed and to provide a piezoelectric vibrator having high reliability.

Moreover, since the piezoelectric vibrator includes the package having excellent airtightness, it is possible to provide a piezoelectric vibrator having excellent vibration characteristics.

According to a still further aspect of the present invention, there is provided an oscillator in which the piezoelectric vibrator according to the above aspect of the present invention is electrically connected to an integrated circuit as an oscillating piece.

With this configuration, it is possible to provide an oscillator having excellent vibration characteristics and high reliability.

According to a still further aspect of the present invention, there is provided an electronic device in which the piezoelectric vibrator according to the above aspect of the present invention is electrically connected to a clock section.

With this configuration, it is possible to provide an electronic device having excellent vibration characteristics and high reliability.

According to a still further aspect of the present invention, there is provided a radio-controlled timepiece in which the piezoelectric vibrator according to the above aspect of the present invention is electrically connected to a filter section.

With this configuration, it is possible to provide a radio-controlled timepiece having excellent vibration characteristics and high reliability.

According to the aspects of the present invention, it is possible to print a marking on the surface of a glass without etching the surface of the glass. Therefore, it is possible to prevent the influence of the laser beam on the electronic component and to provide a package having high reliability.

Moreover, since the marking is printed by removing the thin film formed on the surface of the glass, it is possible to print a clean marking as compared to the case of etching the surface of the glass and to prevent the occurrence of cracks.

### BRIEF DESCRIPTION OF THE DRAWINGS

FIG. 1 is a perspective view showing an external appearance of a piezoelectric vibrator according to an embodiment of the present invention.

FIG. 2 is a top view showing an inner structure of the piezoelectric vibrator according to the embodiment of the present invention, showing a state where a lid substrate is removed.

FIG. 3 is a cross-sectional view of the piezoelectric vibrator taken along the line A-A in FIG. 2.

FIG. 4 is an exploded perspective view of the piezoelectric vibrator shown according to the embodiment of the present invention.

FIG. 5 is a flowchart of the manufacturing method of a piezoelectric vibrator according to an embodiment of the present invention.

FIG. 6 is an exploded perspective view of a wafer assembly according to an embodiment of the present invention.

FIG. 7 is a view illustrating a marking step according to the embodiment of the present invention.

FIGS. 8A and 8B are graphs showing changes in transmittance of a soda-lime glass according to the embodiment of the present invention, in which FIG. 8A shows a case where a wavelength region of a laser beam is 0 μm to 24 μm, and FIG. 8B shows a case where the wavelength region of the laser beam is 100 nm to 1,100 nm.

FIG. 9 is a view showing the schematic configuration of an oscillator according to an embodiment of the present invention.

FIG. 10 is a view showing the schematic configuration of a mobile information device according to an embodiment of the present invention.

FIG. 11 is a view showing the schematic configuration of a radio-controlled timepiece according to an embodiment of the present invention.

FIGS. 12A and 12B are views illustrating a thin film forming step according to a second embodiment of the present invention, in which FIG. 12A is a top view, and FIG. 12B is a cross-sectional view taken along the line B-B in FIG. 12A.

### DETAILED DESCRIPTION OF THE PREFERRED EMBODIMENTS

### Piezoelectric Vibrator

Hereinafter, an embodiment of the present invention will be described with reference to the drawings.

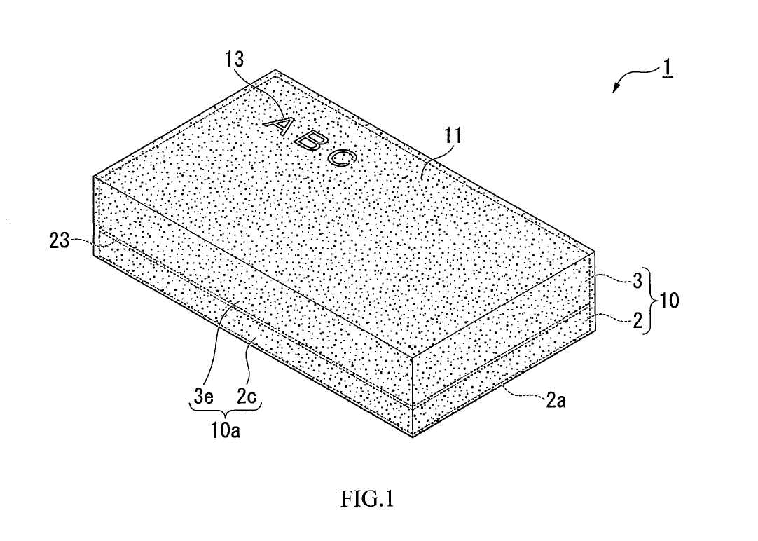

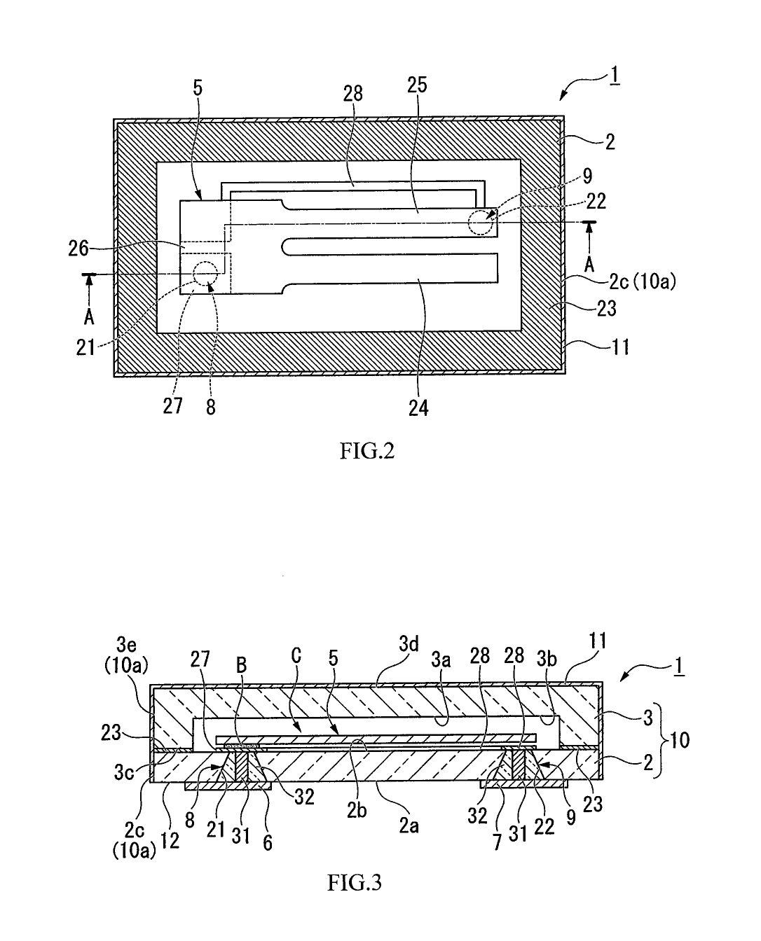

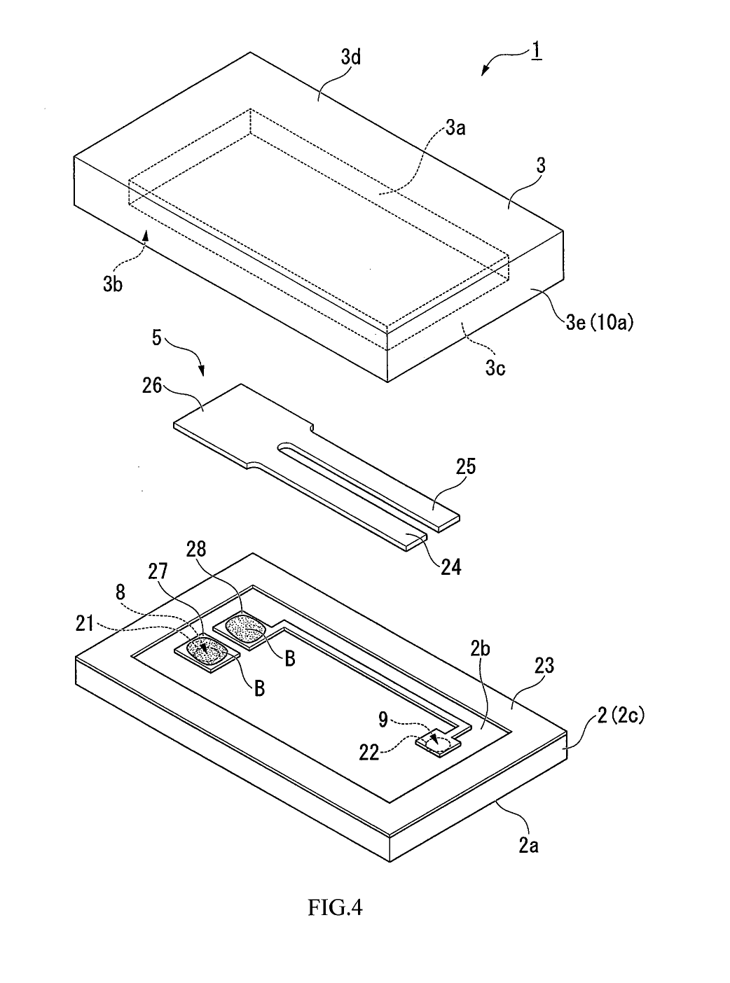

FIG. 1 is a perspective view showing an external appearance of a piezoelectric vibrator according to an embodiment of the present invention, and FIG. 2 is a top view showing an inner structure of the piezoelectric vibrator according to the embodiment of the present invention, showing a state where a lid substrate is removed. FIG. 3 is a cross-sectional view of the piezoelectric vibrator taken along the line A-A in FIG. 2, and FIG. 4 is an exploded perspective view of the piezoelectric vibrator shown according to the embodiment of the present invention.

As shown in FIGS. 1 to 4, a piezoelectric vibrator 1 according to the present embodiment is a surface mounted device-type piezoelectric vibrator 1 which includes a box-shaped package 10, in which a base substrate (first substrate) 2 and a lid substrate (second substrate) 3 are anodically bonded by a bonding material 23, and a piezoelectric vibrating reed (electronic component) 5 which is accommodated in a cavity C of the package 10. The piezoelectric vibrating reed 5 and outer electrodes 6 and 7 which are provided on a rear surface 2a (the lower surface in FIG. 3) of the base substrate 2 are electrically connected by a pair of penetration electrodes 8 and 9 penetrating through the base substrate 2.

The base substrate 2 is a transparent insulating substrate made of a glass material, for example, soda-lime glass, and is formed in a plate-like form. The base substrate 2 is formed with a pair of through-holes 21 and 22 in which a pair of penetration electrodes 8 and 9 is formed. The through-holes 21 and 22 are formed in a tapered form in cross-sectional view whose diameter gradually decreases from the rear surface 2a of the base substrate 2 towards the front surface 2b (the upper surface in FIG. 3).

The lid substrate 3 is a transparent insulating substrate made of glass material, for example, soda-lime glass, similarly to the base substrate 2, and is formed in a plate-like form having a size capable of being superimposed onto the base substrate 2. Moreover, a rectangular recess portion 3a in which the piezoelectric vibrating reed 5 is accommodated is formed on the rear surface 3b (the lower surface in FIG. 3) side of the lid substrate 3.

The recess portion 3a forms a cavity C that accommodates the piezoelectric vibrating reed 5 when the base substrate 2 and the lid substrate 3 are superimposed onto each other. Moreover, the lid substrate 3 is anodically bonded to the base substrate 2 with a bonding material 23 disposed therebetween in a state where the recess portion 3a faces the base substrate 2. That is, the recess portion 3a which is formed at the central portion and a frame region 3c which is formed around the recess portion 3a and serves as a bonding surface to be bonded to the base substrate 2 are formed on the rear surface 3b side of the lid substrate 3.

The piezoelectric vibrating reed 5 is a tuning-fork type vibrating reed which is made of a piezoelectric material such as crystal, lithium tantalate, or lithium niobate and is configured to vibrate when a predetermined voltage is applied thereto.

The piezoelectric vibrating reed 5 is a tuning-fork piezoelectric vibrating reed which includes a pair of vibrating arms 24 and 25 disposed approximately in parallel to each other and a base portion 26 to which the base end sides of the pair of vibrating arms 24 and 25 are integrally fixed. On the surfaces of the pair of vibrating arms 24 and 25, an excitation electrode which allows the pair of vibrating arms 24 and 25 to vibrate and includes a pair of first and second excitation electrodes (not shown); and a pair of mount electrodes (not shown) which electrically connects the first and second excitation electrodes to lead-out electrodes 27 and 28 described later are provided.

As shown in FIGS. 2 and 3, the piezoelectric vibrating reed 5 configured in this way is bump-bonded on the lead-out electrodes 27 and 28, which are formed on the front surface 2b of the base substrate 2, using bumps B made of gold or the like.

More specifically, the first excitation electrode of the piezoelectric vibrating reed 5 is bump-bonded on one lead-out electrode 27 via one mount electrode and the bumps B. Moreover, the second excitation electrode is bump-bonded on the other lead-out electrode 28 via the other mount electrode and the bumps B. In this way, the piezoelectric vibrating reed 5 is supported in a state of being floated from the front surface 2b of the base substrate 2, and the respective mount electrodes and the lead-out electrodes 27 and 28 are electrically connected to each other.

A bonding material 23 for anodic bonding made of Al is formed on the front surface 2b side of the base substrate 2 (the bonding surface side to be bonded to the lid substrate 3). The bonding material 23 has a thickness of about 3000 Å to 5000 Å, for example, and is formed along the outer circumferential portion of the base substrate 2 so as to face the frame region 3c of the lid substrate 3.

Moreover, the bonding material 23 and the frame region 3c of the lid substrate 3 are anodically bonded to each other, whereby the cavity C is vacuum-sealed. The side surfaces of the bonding material 23 are formed to be approximately flush with the side surfaces 2c and 3e (the side surface (outer side surface) 10a of the package 10) of the base substrate 2 and the lid substrate 3.

The outer electrodes 6 and 7 are provided on both sides in the longitudinal direction of the rear surface 2a of the base substrate 2 (the surface on the opposite side to the bonding surface of the base substrate 2). The outer electrodes 6 and 7 are electrically connected to the piezoelectric vibrating reed 5 via the penetration electrodes 8 and 9 and the lead-out electrodes 27 and 28.

More specifically, one outer electrode 6 is electrically connected to one mount electrode of the piezoelectric vibrating reed 5 via one penetration electrode 8 and one lead-out electrode 27. On the other hand, the other outer electrode 7 is electrically connected to the other mount electrode of the piezoelectric vibrating reed 5 via the other penetration electrode 9 and the other lead-out electrode 28.

Moreover, the side surfaces (the outer circumferences) of the outer electrodes 6 and 7 are positioned on the inner side than the side surfaces 2c of the base substrate 2.

The penetration electrodes 8 and 9 are formed by a cylindrical member 32 and a core portion 31 which are integrally fixed to the through-holes 21 and 22 by baking. The penetration electrodes 8 and 9 serve to maintain airtightness of the cavity C by completely closing the through-holes 21 and 22 and achieving electrical connection between the outer electrodes 6 and 7 and the lead-out electrodes 27 and 28.

Specifically, one penetration electrode 8 is disposed below the lead-out electrode 27 and between the outer electrode 6 and the base portion 26. The other penetration electrode 9 is disposed below the lead-out electrode 28 and between the outer electrode 7 and the vibrating arm 25.

The cylindrical member 32 is obtained by baking a paste-like glass frit. The cylindrical member 32 has a cylindrical shape in which both ends are flat and which has approximately the same thickness as the base substrate 2. The core portion 31 is disposed at the center of the cylindrical member 32 so as to penetrate through the central hole of the cylindrical member 32.

In the present embodiment, the cylindrical member 32 has an approximately conical outer shape (a tapered cross-sectional shape) so as to comply with the shapes of the through-holes 21 and 22. The cylindrical member 32 is baked in a state of being buried in the through-holes 21 and 22 and is tightly attached to the through-holes 21 and 22.

The core portion 31 is a conductive cylindrical core material made of metallic material, and similarly to the cylindrical member 32, has a shape which has flat ends and approximately the same thickness as the base substrate 2. The electrical connection of the penetration electrodes 8 and 9 is secured via the conductive core portion 31.

As shown in FIGS. 1 to 3, a thin film 11 is formed on the package 10 so as to cover the entire region including the front surface 3d of the lid substrate 3, the side surfaces 3e of the lid substrate 3, and the side surfaces 2c (the side surfaces 10a of the package 10) of the base substrate 2. That is, the thin film 11 is formed so as to cover the bonding material 23 which is exposed to the outside from the gap between the base substrate 2 and the lid substrate 3. Moreover, the peripheral edge portion (the lower end in FIG. 3) of the thin film 11 is formed to be approximately flush with the rear surface 2a of the base substrate 2. That is, the thin film 11 is not formed on the rear surface 2a of the base substrate 2.

By forming the thin film 11 in such a way, it is possible to improve adhesion between the thin film 11, the base substrate 2, and the lid substrate 3 and to suppress a gap from being formed between the thin film 11 and the substrates 2 and 3 or separation of the thin film 11.

The thin film 11 is formed of a metallic material containing silicon (Si) as its main component and the thickness T of the thin film 11 is set so as to satisfy the following relational expression (1).

1000 Å≦T≦3000 Å (1)

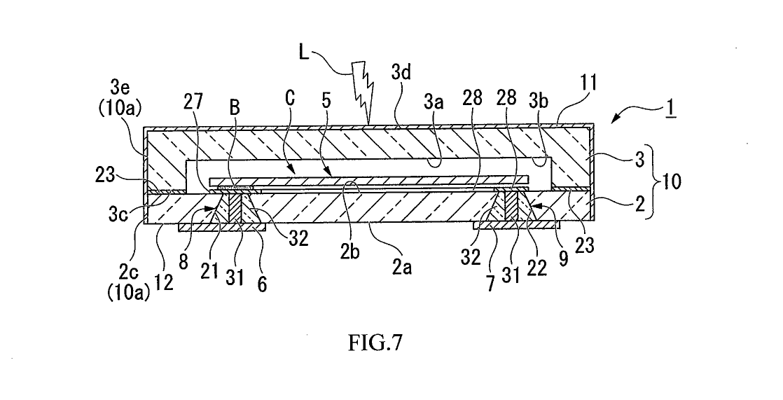

Moreover, a marking 13 indicating a product type, a product number, or the date of manufacturing is printed on the thin film 11 formed on the front surface 3d of the lid substrate 3. The marking 13 is printed by irradiating the thin film 11 with a laser beam L (see FIG. 7) to remove a part of the thin film 11 (the details of which will be described later).

By forming the thin film 11 using a metallic material containing silicon (Si) having a high absorption ratio to the laser beam L as its main component, it is possible to reliably print the marking 13 on the thin film 11 formed on the front surface 3d of the lid substrate 3.

When the piezoelectric vibrator 1 configured in this manner is operated, a predetermined driving voltage is applied between the pair of outer electrodes 6 and 7 formed on the base substrate 2. In this way, a current can be made to flow to the excitation electrodes of the piezoelectric vibrating reed 5, and the pair of vibrating arms 24 and 25 is allowed to vibrate at a predetermined frequency in a direction moving closer to or away from each other. This vibration of the pair of vibrating arms 24 and 25 can be used as the time source, the timing source of a control signal, the reference signal source, and the like.

### Piezoelectric Vibrator Manufacturing Method

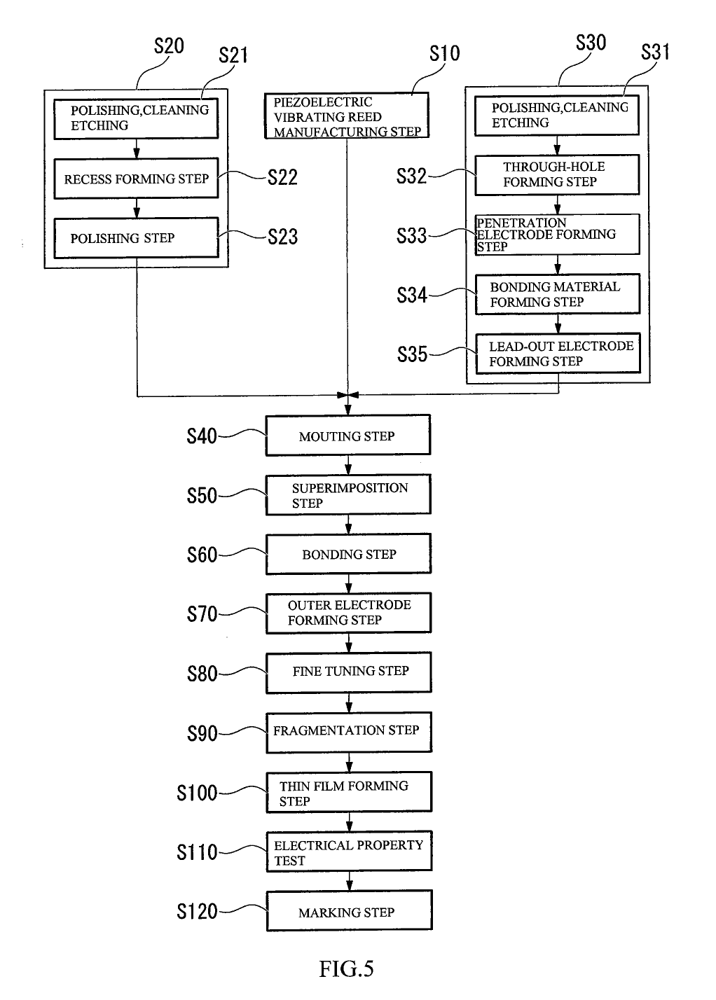

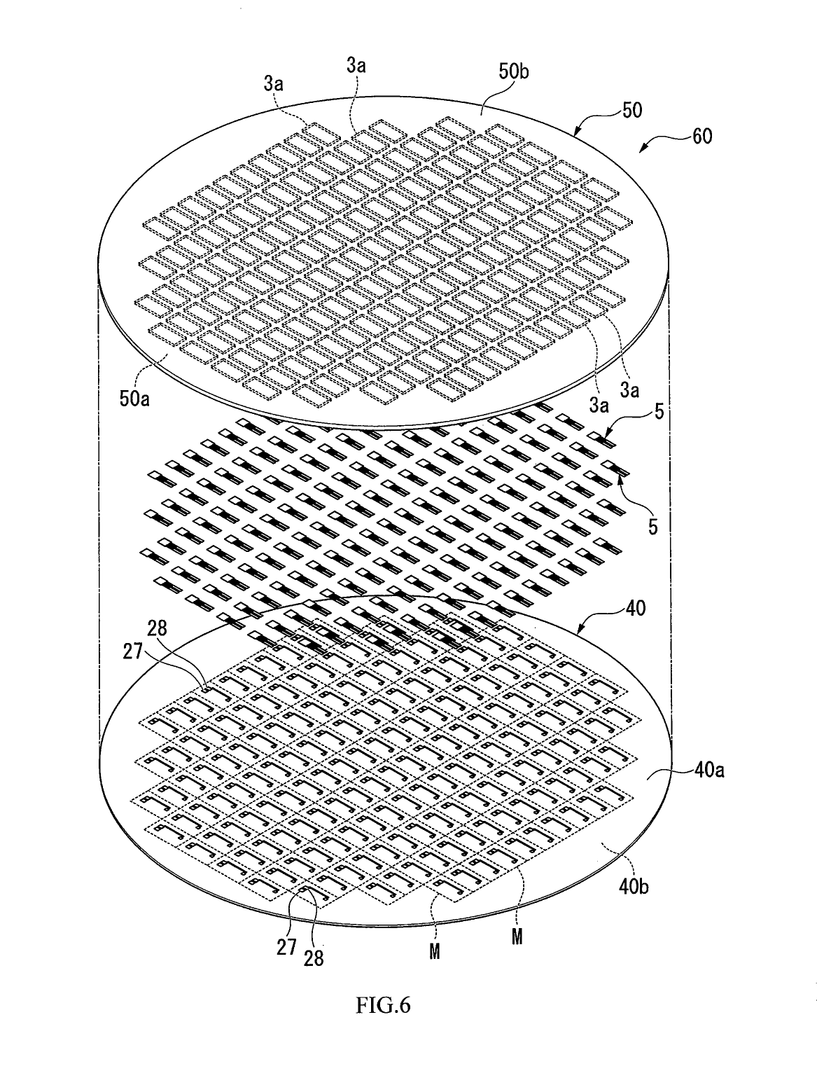

Next, a method for manufacturing the piezoelectric vibrator 1 will be described with reference to FIGS. 5 and 6.

FIG. 5 is a flowchart of the manufacturing method of the piezoelectric vibrator 1 according to an embodiment of the present invention, and FIG. 6 is an exploded perspective view of a wafer assembly 60 according to an embodiment of the present invention.

In the manufacturing method of the piezoelectric vibrator 1, a method of manufacturing a plurality of piezoelectric vibrators (assembled fragments) at a time by sealing a plurality of piezoelectric vibrating reeds 5 between a base substrate wafer 40 including a plurality of base substrates 2 and a lid substrate wafer 50 including a plurality of lid substrates 3 to form a wafer assembly 60 and cutting the wafer assembly 60 to obtain the plurality of piezoelectric vibrators 1 will be described. The dotted line M shown in the respective figures starting with FIG. 6 is a cutting line along which a cutting step performed later is achieved.

The manufacturing method of the piezoelectric vibrator 1 according to the present embodiment mainly includes a piezoelectric vibrating reed manufacturing step (S10), a lid substrate wafer manufacturing step (S20), a base substrate wafer manufacturing step (S30), and an assembling step (S40 and subsequent steps). Among the steps, the piezoelectric vibrating reed manufacturing step (S10), the lid substrate wafer manufacturing step (S20), and the base substrate wafer manufacturing step (S30) can be performed in parallel.

First, as shown in FIG. 5, a piezoelectric vibrating reed manufacturing step is performed to manufacture the piezoelectric vibrating reed 5 (S10). Moreover, after the piezoelectric vibrating reed 5 is manufactured, rough tuning of the resonance frequency is performed. Fine tuning of adjusting the resonance frequency more accurately is performed after a mounting step is performed.

### Lid Substrate Wafer Manufacturing Step

Subsequently, as shown in FIGS. 5 and 6, a lid substrate wafer manufacturing step is performed where a lid substrate wafer 50 later serving as the lid substrate 3 is manufactured up to a stage immediately before anodic bonding is achieved (S20).

Specifically, a disk-shaped lid substrate wafer 50 is formed by polishing a soda-lime glass to a predetermined thickness, cleaning the polished glass, and removing the affected uppermost layer by etching or the like (S21).

After that, a recess forming step is performed where a plurality of recess portions 3a to be used as a cavity C is formed in a matrix form on the rear surface 50a (the lower surface in FIG. 6) of the lid substrate wafer 50 by etching or the like (S22).

Subsequently, in order to secure airtightness between the lid substrate wafer 50 and a base substrate wafer 40 described later, a polishing step (S23) is performed where at least the rear surface 50a of the lid substrate wafer 50 serving as the bonding surface to be bonded to the base substrate wafer 40 is polished so that the rear surface 50a has a mirror-like surface. In this way, the lid substrate wafer manufacturing step (S20) ends.

### Base Substrate Wafer Manufacturing Step

Subsequently, at the same or a different time as the lid substrate wafer manufacturing step, a base substrate wafer manufacturing step is performed where a base substrate wafer 40 later serving as the base substrate 2 is manufactured up to a stage immediately before anodic bonding is achieved (S30).

First, a disk-shaped base substrate wafer 40 is formed by polishing a soda-lime glass to a predetermined thickness, cleaning the polished glass, and removing the affected uppermost layer by etching or the like (S31).

After that, a through-hole forming step is performed where a plurality of through-holes 21 and 22 for disposing a pair of penetration electrodes 8 and 9 on the base substrate wafer 40 is formed by press working or the like (S32).

Specifically, the through-holes 21 and 22 can be formed by forming recess portions on the rear surface 40b of the base substrate wafer 40 by press working or the like and then polishing at least the front surface 40a of the base substrate wafer 40 so as to penetrate through the recess portions.

Subsequently, a penetration electrode forming step (S33) is performed where penetration electrodes 8 and 9 are formed in the through-holes 21 and 22 formed during the through-hole forming step (S32).

By doing so, in the through-holes 21 and 22, the core portions 31 are maintained to be flush with both surfaces 40a and 40b (the upper and lower surfaces in FIG. 6) of the base substrate wafer 40. In this way, the penetration electrodes 8 and 9 can be formed.

Subsequently, a bonding material forming step is performed where a conductive material is patterned on the front surface 40a of the base substrate wafer 40 so as to form a bonding material 23 (S34), and a lead-out electrode forming step is performed (S35).

The bonding material 23 is formed on a region of the base substrate wafer 40 other than the formation region of the cavity C, namely the entire bonding region of the lid substrate wafer 50 to be bonded to the rear surface 50a of the lid substrate wafer 50. In this way, the base substrate wafer manufacturing step (S30) ends.

Subsequently, the piezoelectric vibrating reed 5 manufactured by the piezoelectric vibrating reed manufacturing step (S10) is mounted on the lead-out electrodes 27 and 28 of the base substrate wafer 40 manufactured by the base substrate wafer manufacturing step (S30) with bumps B made of gold or the like disposed therebetween (S40).

Then, a superimposition step is performed where the base substrate wafer 40 and the lid substrate wafer 50 manufactured by the manufacturing steps of the respective wafers 40 and 50 are superimposed onto each other (S50).

Specifically, the two wafers 40 and 50 are aligned at a correct position using reference marks or the like not shown in the figure as indices. In this way, the mounted piezoelectric vibrating reed 5 is accommodated in the cavity C surrounded by the recess portion 3a formed on the lid substrate wafer 50 and the base substrate wafer 40.

After the superimposition step is performed, a bonding step is performed where anodic bonding is achieved under a predetermined temperature atmosphere with application of a predetermined voltage in a state where the two superimposed wafers 40 and 50 are inserted into an anodic bonding machine not shown and the outer peripheral portions of the wafers are clamped by a holding mechanism not shown (S60).

Specifically, a predetermined voltage is applied between the bonding material 23 and the lid substrate wafer 50. Then, an electrochemical reaction occurs at an interface between the bonding material 23 and the lid substrate wafer 50, whereby they are closely adhered tightly and anodically bonded. In this way, the piezoelectric vibrating reed 5 can be sealed in the cavity C, and a wafer assembly 60 can be obtained in which the base substrate wafer 40 and the lid substrate wafer 50 are bonded to each other.

According to the present embodiment, by anodically bonding the two wafers 40 and 50, compared to the case of bonding the two wafers 40 and 50 by an adhesive or the like, it is possible to prevent positional shift due to aging or impact and warping of the wafer assembly 60 and bond the two wafers 40 and 50 more tightly.

In this case, in the present embodiment, since Al having a relatively low resistance is used for the bonding material 23, it is possible to apply a uniform voltage to the entire surface of the bonding material 23 and to easily form the wafer assembly 60 in which the bonding surfaces of the two wafers 40 and 50 are tightly anodically bonded to each other. Moreover, since the anodic bonding can be achieved with a relatively low voltage, it is possible to decrease energy consumption and to reduce the manufacturing cost.

After that, a pair of outer electrodes 6 and 7 is formed so as to be electrically connected to the pair of penetration electrodes 8 and 9 (S70), and the frequency of the piezoelectric vibrator 1 is finely tuned (S80).

After the fine tuning of the frequency is completed, a fragmentation step is performed where the bonded wafer assembly 60 is cut into small fragments (S90).

In the fragmentation step (S90), the wafer assembly 60 is maintained on a magazine (not shown), and a surface layer portion of a front surface 50b of the lid substrate wafer 50 is irradiated with a laser beam along the cutting line M to form a scribe line on the wafer assembly 60. Moreover, breaking is performed on the wafer assembly 60 on which the scribe line is formed, and a breaking stress is applied to the wafer assembly 60. By doing so, a crack is formed on the wafer assembly 60 along the thickness direction, and the wafer assembly 60 is cut in such a way that it is divided along the scribe line formed on the lid substrate wafer 50. By pressing a cutting blade (not shown) on each scribe line, it is possible to divide the wafer assembly 60 into packages 10 (piezoelectric vibrators 1) for each cutting line M at once.

After the fragmentation step is finished, a thin film forming step (S100) is performed where the package 10 is coated with the thin film 11.

For example, the thin film 11 can be formed by a deposition method such as a sputtering method, a vacuum deposition method, or a CVD method. Here, when forming the thin film 11 so as to cover the entire region of the package 10 including the front surface 3d of the lid substrate 3, the side surfaces 3e of the lid substrate 3, and the side surfaces 2c (the side surfaces 10a of the package 10) of the base substrate 2, it is preferable to attach a UV tape, for example, on the rear surface 2a of the base substrate 2. As the UV tape, a polyolefin sheet coated with an adhesive made of a UV-curable resin can be used, for example.

At the stage where the fragmentation step is performed, the rear surface 40b side (the outer electrodes 6 and 7 side) of the base substrate wafer 40 may be attached to the adhesion surface of the UV tape. By doing so, the fragmentation step and the thin film forming step can be performed by a series of operations.

That is, since an expanding step of expanding the UV tape is performed after the fragmentation step is finished, a plurality of packages 10 is disposed on the UV tape with a predetermined gap therebetween. By performing the thin film forming step in such a state, it is possible to form the thin film 11 so as to cover the entire region of the package 10 including the front surface 3d of the lid substrate 3, the side surfaces 3e of the lid substrate 3, and the side surfaces 2c (the side surfaces 10a of the package 10) of the base substrate 2.

By performing the fragmentation step and the thin film forming step by a series of operations, it is possible to improve the manufacturing efficiency as compared to the case of forming the thin film 11 separately on the packages 10.

Furthermore, by performing the thin film forming step in a state where the UV tape is attached to the rear surface 2a side of the base substrate 2, it is possible to suppress the deposition material from being scattered to adhere onto the rear surface 2a side of the base substrate 2. Therefore, it is possible to suppress the deposition material from being adhered to the outer electrodes 6 and 7, and the respective outer electrodes 6 and 7 are suppressed from being bridged by the thin film 11.

When the bonding material 23 made of Al or the like is exposed to the outside, corrosion may progress from the exposed portion, and it is unable to maintain the airtightness of the package 10. In contrast, by forming the thin film 11 made of Si or the like having excellent resistance to corrosion on the side surfaces of the package 10 and cover the bonding material 23 exposed to the outside from the gap between the base substrate 2 and the lid substrate 3 with the thin film 11, it is possible to prevent corrosion of the bonding material 23.

Moreover, when the UV tape is attached to the rear surface 2a of the base substrate 2, it is necessary to perform a pickup step after the thin film forming step so as to pick up the piezoelectric vibrators 1 on which the thin film 11 is formed.

More specifically, in the pickup step, first, the UV tape is irradiated with a UV beam so as to decrease the adhesion force of the UV tape. In this way, the piezoelectric vibrators 1 are separated from the UV tape. Thereafter, the piezoelectric vibrators 1 are sucked by a nozzle or the like while detecting the positions thereof through image recognition or the like, whereby the piezoelectric vibrators 1 separated from the UV tape are picked up.

Subsequently, an inner electrical property test is conducted so as to check the electrical properties of the fragmented piezoelectric vibrators 1 (S110).

That is, the resonance frequency, resonance resistance value, drive level properties (the excitation power dependence of the resonance frequency and the resonance resistance value), and the like of the piezoelectric vibrating reed 5 are measured and checked. Moreover, the insulation resistance value properties and the like are checked as well. Finally, an external appearance test of the piezoelectric vibrator 1 is conducted to check the dimensions, the quality, and the like.

### Marking Step

Next, a marking step will be described with reference to FIGS. 5 and 7.

FIG. 7 is a view illustrating a marking step according to the embodiment of the present invention.

As shown in FIGS. 5 and 7, a marking step is performed where a marking 13 is finally printed on the piezoelectric vibrators 1 for which the electrical property test and the external appearance test have been completed, and which passed the tests (S120).

The marking 13 is printed by irradiating the front surface 3d of the lid substrate 3 with a laser beam L from a vertical direction to remove the thin film 11 on the front surface 3d of the lid substrate 3.

Here, as the laser beam L, a laser beam in a wavelength region in which 100% thereof is absorbed in the lid substrate 3 made of a soda-lime glass is used. More preferably, a laser beam having a longer wavelength in the wavelength region in which 100% thereof is absorbed in the lid substrate 3 is used.

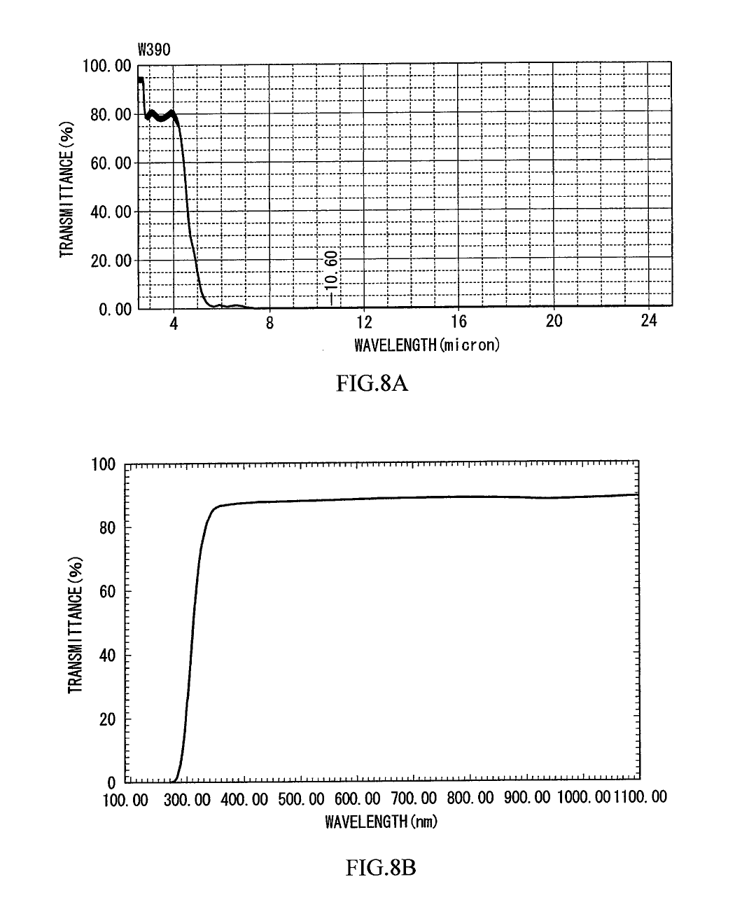

This will be described in more detail with reference to FIGS. 8A and 8B.

FIGS. 8A and 8B are graphs showing changes in transmittance of a soda-lime glass according to the embodiment of the present invention when the vertical axis is the transmittance of the soda-lime glass and the horizontal axis is the wave-length of the laser beam. Specifically, FIG. 8A shows a case where a wavelength region of a laser beam is 0 μm to 24 μm, and FIG. 8B shows a case where the wavelength region of the laser beam is 100 nm to 1,100 nm.

As shown in FIGS. 8A and 8B, it can be understood that a region in which 100% of the laser beam is absorbed in the soda-lime glass, namely a region in which the transmittance is 0% includes a region in which the wavelength λ of the laser beam is shorter than about 240 nm and a region in which the wavelength λ, is longer than about 7.2 μm.

Since the energy of the laser beam increases as the wavelength decreases, when a laser beam (see FIG. 8B) in the short wavelength region is used, there is a possibility that the laser beam removes the thin film 11 at the time of the marking step and also forms cracks or the like on the front surface 3d of the lid substrate 3.

Therefore, a laser beam having a short wavelength, for example, a laser beam having a wavelength of about 300 nm is used for the fragmentation step of forming a scribe line on the wafer assembly 60 or in the case of performing etching on the glass itself as in the related art.

In contrast, by using a laser beam (see FIG. 8A) having a long wavelength, namely a laser beam having a wavelength λ satisfying the following relational expression (2) as the laser beam L, it is possible to prevent the occurrence of cracks on the front surface 3d of the lid substrate 3.

λ≦7.5 μm (2)

More specifically, it is preferable to use a CO₂ laser as the laser beam L. The wavelength λ, of the CO₂ laser is 10.6 μm, the relational expression (2) is satisfied.

Even when the CO2 laser is used as the laser beam L, if the output of the laser beam L is increased, there is a possibility that cracks are formed on the front surface 3d of the lid substrate 3. Therefore, when the thickness T of the thin film 11 is set so as to satisfy the relational expression (1), namely 1000 Å≦T≦3000 Å, it is preferable to set the output P of the laser beam so as to satisfy the following relational expression (3).

4.5 W≦P≦6.0 W (3)

When the output P of the laser beam L satisfies the relational expression (3), the laser beam L will remove only the thin film 11, and 100% of the laser beam L will be absorbed in the lid substrate 3 without forming cracks (see FIG. 7).

When etching is performed on the glass itself as in the related art, the energy density of the laser beam is generally set to 0.7 J/cm² to 20 J/cm², for example.

Moreover, a portion of the front surface 3d of the lid substrate 3 in which the thin film 11 is removed by the laser beam L is exposed to the outside. Here, since the thin film 11 is made of a metallic material containing silicon (Si) as its main component, and the thickness T thereof is set so as to satisfy the relational expression (1), the thin film 11 exhibits a color such as light purple, pink, or gray. Therefore, the colors of the exposed portion of the front surface 3d of the lid substrate 3 and the thin film 11 are clearly distinguished.

When the thin film 11 is not completely removed and the front surface 3d of the lid substrate 3 is not exposed from the removed portion, the colors of the removed portion and the remaining portion are not clearly distinguished. Thus, it is difficult to visually recognize the marking.

According to the above-described embodiment, by forming the thin film 11 so as to cover the entire region including the front surface 3d of the lid substrate 3, the side surfaces 3e of the lid substrate 3, and the side surfaces 2c (the side surfaces 10a of the package 10) of the base substrate 2 and removing the thin film 11 using the laser beam L, it is possible to print a marking on the front surface 3d of the lid substrate 3. Therefore, it is not necessary to etch the front surface 3d of the lid substrate 3 as in the related art. Therefore, it is possible to prevent the influence of the laser beam L on the piezoelectric vibrating reed 5 and to provide the package 10 (the piezoelectric vibrator 1) having high reliability.

Moreover, it is possible to print a clean marking as compared to the case of etching the front surface 3d of the lid substrate 3 as in the related art. In addition, it is possible to reliably prevent the occurrence of cracks in the lid substrate 3.

Moreover, by using the CO₂ laser as the laser beam L used in the marking step, it is possible to reliably prevent the laser beam from passing through the lid substrate 3. Therefore, it is possible to provide the package 10 (the piezoelectic vibrator 1) having higher reliability.

Moreover, by setting the thickness T of the thin film 11 so as to satisfy the relational expression (1) and setting the output P of the laser beam L so as to satisfy the relational expression (3), it is possible to reliably remove the thin film 11 so that the front surface 3d of the lid substrate 3 is exposed from the removed portion and to allow 100% of the laser beam L to be absorbed in the lid substrate 3.

Furthermore, by forming the thin film 11 using a metallic material containing silicon (Si) as its main component, it is possible to print a cleaner marking on the front surface 3d of the lid substrate 3. In addition, since silicon (Si) has high resistance to corrosion and high insulating properties, it is possible to increase the reliability of the package 10 (the piezoelectric vibrator 1).

In the above-described embodiment, a case where the thin film 11 is formed of a metallic material containing silicon (Si) as its main component has been described. However, the present invention is not limited to this, and other metallic materials such as chromium (Cr) or titanium (Ti) having higher resistance to corrosion (lower ionization tendency) than the bonding material 23 may be used instead of silicon (Si).

In this case, it is necessary to set the wavelength λ, and the output P of the laser beam L separately. That is, the wavelength λ, and the output P of the laser beam L are not limited to the case of satisfying the relational expressions (2) and (3), but the laser beam L only needs to be capable of preventing the occurrence of cracks in the lid substrate 3 while removing the thin film 11 at the time of irradiating the thin film 11 with the laser beam L after the thin film 11 is formed on the front surface 3d of the lid substrate 3, and the laser beam L only needs to ensure that 100% of the laser beam L is absorbed in the lid substrate 3.

Moreover, even when the thin film 11 is formed of chromium (Cr) or titanium (Ti) instead of silicon (Si), since the side surfaces of the outer electrodes 6 and 7 of the piezoelectric vibrator 1 are positioned on the inner side than the side surfaces 2c of the base substrate 2 (see FIG. 3), the outer electrodes 6 and 7 are not bridged by the thin film 11. Thus, it is possible to prevent short-circuiting of the outer electrodes 6 and 7.

Furthermore, in the above-described embodiment, a case where the thin film 11 is formed so as to cover the entire region including the front surface 3d of the lid substrate 3, the side surfaces 3e of the lid substrate 3, and the side surfaces 2c (the side surfaces 10a of the package 10) of the base substrate 2 has been described. However, the present invention is not limited to this, and the thin film 11 may only need to be formed on at least the front surface 3d of the lid substrate 3.

In this case, it is not necessary to perform the thin film forming step after the fragmentation step is finished, and the thin film 11 may be formed on the front surface of the lid substrate wafer 50 in a state where the front surface of the lid substrate wafer 50 has been polished (polishing step) in the lid substrate wafer manufacturing step, for example. By forming the thin film 11 in the state of the lid substrate wafer 50 as described above, the thin film 11 can be used as a film that neutralizes the charges during the bonding step.

That is, in the bonding step of anodically bonding the lid substrate wafer 50 and the base substrate wafer 40, a negative charge layer is formed on the front surface side of the lid substrate wafer 50. However, since the thin film 11 containing Si as its main component is formed on the front surface of the lid substrate wafer 50, the negative charge layer is neutralized by the thin film 11. In this way, no polarization will occur in the lid substrate wafer 50, and anodic bonding can be performed reliably.

Moreover, in the above-described embodiment, a case where the base substrate 2 and the lid substrate 3 are formed of a glass material (for example, a soda-lime glass) has been described. However, the present invention is not limited to this, and at least a portion of the base substrate 2 and the lid substrate 3 on which the marking 13 is printed may only need to be formed of a glass material. That is, in the present embodiment, at least a portion of the front surface 3d of the lid substrate 3 on which the marking 13 is printed may be formed of a glass material.

Furthermore, in the above-described embodiment, a case where the marking 13 is printed on the front surface 3d of the lid substrate 3 has been described. However, the present invention is not limited to this, and the marking 13 may be printed on the rear surface 2a of the base substrate 2. In this case, since the outer electrodes 7 and 8 are formed on the rear surface 2a of the base substrate 2, it is necessary to forming the thin film 11 so as not to overlap with these outer electrodes 7 and 8.

### Second Embodiment

Next, a second embodiment of the present invention will be described. Although the thin film forming step (S100; see FIG. 5) of the first embodiment is performed in a state where the package attached to the UV tape, a thin film forming step of the second embodiment is performed in a state where the package is disposed in a recess portion of a thin film forming jig. The detailed description of the same configurations as the first embodiment will be omitted.

In the second embodiment, the steps up to the fragmentation step (S90) are performed similarly to the first embodiment. That is, the wafer assembly 60 is fragmented into a plurality of packages 10 (piezoelectric vibrators 1) in a state where a UV tape is attached to the wafer assembly 60. Subsequently, in the second embodiment, the UV tape is irradiated with a UV beam so as to decrease the adhesion force of the UV tape. The fragmented packages 10 are picked up and placed on a thin film forming jig described later.

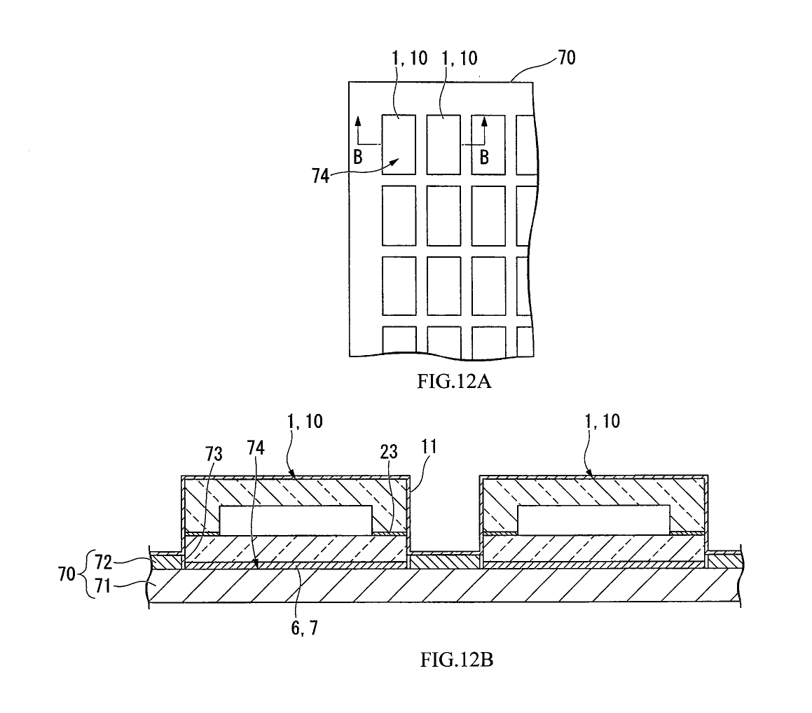

FIGS. 12A and 12B are views illustrating a thin film forming step according to the second embodiment of the present invention, in which FIG. 12A is a top view, and FIG. 12B is a cross-sectional view taken along the line B-B in FIG. 12A. In FIG. 12B, the illustrations of inclusions of the package 10 are omitted. In the second embodiment, the thin film forming step is performed with the package 10 disposed on a thin film forming jig 70.

As shown in FIG. 12B, the thin film forming jig 70 is formed by stacking a support plate 71 made of Al or the like and a cover plate 72 made of stainless steel or the like. The cover plate 72 has penetration holes 73, and the bottom openings of the penetration holes 73 are closed by the support plate 71, whereby recess portions 74 are formed in the thin film forming jig 70.

As shown in FIG. 12A, the recess portions 74 have the same rectangular shape as the packages 10 in a planar view thereof. A plurality of recess portions 74 is formed in the thin film forming jig 70, and the respective recess portions 74 are arranged in a matrix form in a state of being mutually spaced from each other. By disposing the packages 10 in the respective recess portions 74, the plurality of packages 10 is disposed to be separated from each other.

As shown in FIG. 12B, the package 10 is disposed in the recess portion 74 so that the outer electrodes 6 and 7 of the package 10 come into contact with the bottom surface of the recess portion 74. Since the depth (the thickness of the cover plate 72) of the recess portion 74 is larger than the thickness of the outer electrodes 6 and 7 of the package 10, the outer electrodes 6 and 7 are accommodated in the recess portion 74. Moreover, the depth of the recess portion 74 is smaller than the height from the bottom surface of the package 10 to the bonding material 23, the bonding material 23 is exposed to the outside.

In the thin film forming step, the thin film 11 is formed in a state where the package 10 is disposed in the recess portion 74 of the thin film forming jig 70. The thin film 11 is formed by a sputtering method using a material such as Si similarly to the first embodiment. As described above, since the outer electrodes 6 and 7 are accommodated in the recess portion 74, the thin film 11 is not formed on the outer electrodes 6 and 7. Therefore, it is possible to prevent short-circuiting of the outer electrodes 6 and 7. Moreover, since a plurality of packages 10 is disposed to be separated from each other, it is possible to form the thin film 11 on the side surfaces of the packages 10. Furthermore, the bonding material 23 is exposed to the outside from the side surfaces of the packages 10 without being accommodated in the recess portions 74. Therefore, it is possible to form the thin film 11 so as to cover the bonding material 23.

Subsequently to the thin film forming step (S100), an electrical property test (S110) and a marking step (S120) are performed. The marking step is performed in a state where the packages 10 are disposed on the thin film forming jig 70. By performing the steps from the thin film forming step to the marking step in a continuous manner without moving the packages 10, it is possible to decrease the manufacturing cost. After that, the packages 10 are picked up from the thin film forming jig.

In this way, the piezoelectric vibrator 1 in which the outer electrodes 6 and 7 are exposed from the lower half portion of the packages 10, the upper half portion thereof is covered with the thin film 11, and a marking is printed is obtained.

As described above, according to the second embodiment, since the thin film is formed in a state where the outer electrodes 6 and 7 of the package 10 are accommodated in the recess portions of the thin film forming jig, it is possible to prevent the short-circuiting of the outer electrodes 6 and 7. Moreover, since the thin film is formed in a state where the bonding material 23 is exposed to the outside, it is possible to cover the bonding material 23 with the thin film. Furthermore, since the thin film is formed in a state where a plurality of packages 10 is disposed to be separated from each other, it is possible to form the thin film on the side surfaces of the packages 10 and to reliably cover the bonding material 23 with the thin film. In this way, since it is possible to prevent corrosion of the bonding material 23, the airtightness of the package 10 can be maintained.

### Oscillator

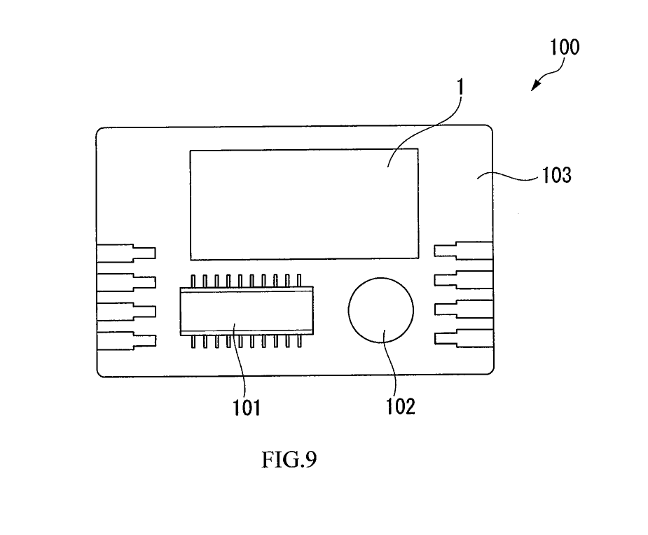

Next, an oscillator according to another embodiment of the invention will be described with reference to FIG. 9.

FIG. 9 is a view showing the schematic configuration of an oscillator 100.

As shown in FIG. 9, the oscillator 100 has a configuration in which the piezoelectric vibrator 1 is used as an oscillating piece electrically connected to an integrated circuit 101. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101.

The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 5 in the piezoelectric vibrator 1 vibrates. This vibration is converted into an electrical signal due to the piezoelectric property of the piezoelectric vibrating reed 5 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

Moreover, by selectively setting the configuration of the integrated circuit 101, for example, an RTC (real time clock) module, according to the demands, it is possible to add a function of controlling the operation date or time of the corresponding device or an external device or of providing the time or calendar in addition to a single functional oscillator for a clock.

As described above, since the oscillator 100 according to the present embodiment includes the piezoelectric vibrator 1 in which the airtightness of the cavity C is secured, it is possible to provide a high-quality oscillator 100 having excellent characteristics and reliability. In addition to this, it is possible to obtain a highly accurate frequency signal which is stable over a long period of time.

### Electronic Device

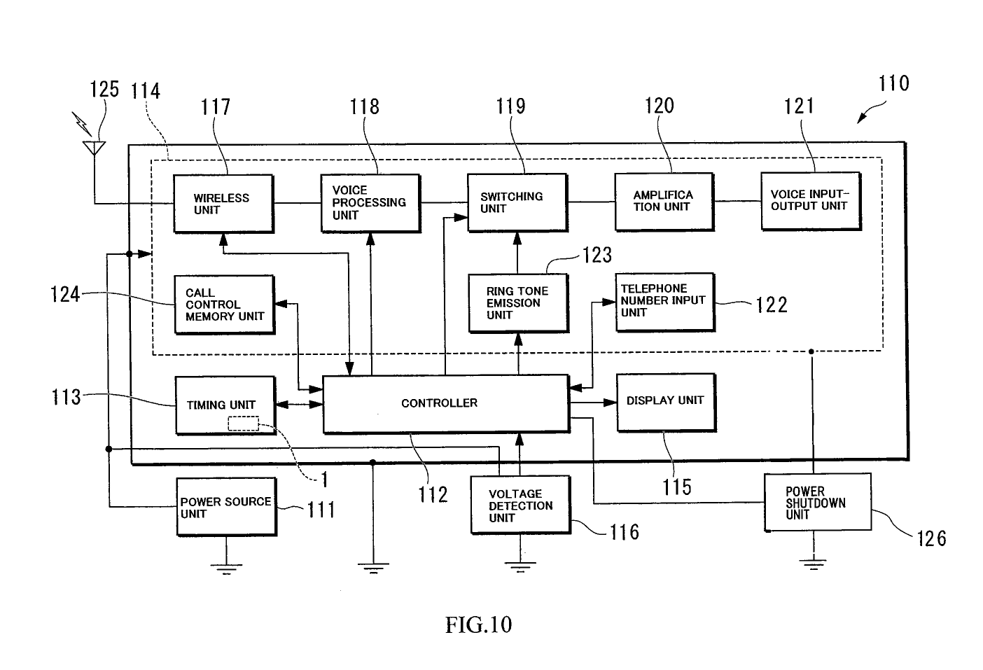

Next, an electronic device according to another embodiment of the invention will be described with reference to FIG. 10. In addition, a portable information device 110 including the piezoelectric vibrator 1 will be described as an example of an electronic device.

FIG. 10 is a view showing the schematic configuration of an electronic device 110.

The portable information device 110 is represented by a mobile phone, for example, and has been developed and improved from a wristwatch in the related art. The portable information device 110 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 110 is very small and light compared with a mobile phone in the related art.

As shown in FIG. 10, the portable information device 110 includes the piezoelectric vibrator 1 and a power supply section 111 for supplying power. The power supply section 111 is formed of a lithium secondary battery, for example. A control section 112 which performs various kinds of control, a clock section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 5 vibrates, and this vibration is converted into an electrical signal due to the piezoelectric property of crystal and is then input to the oscillation circuit as the electrical signal.

The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound louder or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set beforehand as the lowest voltage necessary to operate the communication section 114 stably. For example, it is about 3 V.

When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 according to the present embodiment includes the piezoelectric vibrator 1 in which the airtightness of the cavity C is secured, it is possible to provide a high-quality portable information device 110 having excellent characteristics and reliability. In addition to this, it is possible to display highly accurate clock information which is stable over a long period of time.

### Radio-Controlled Timepiece

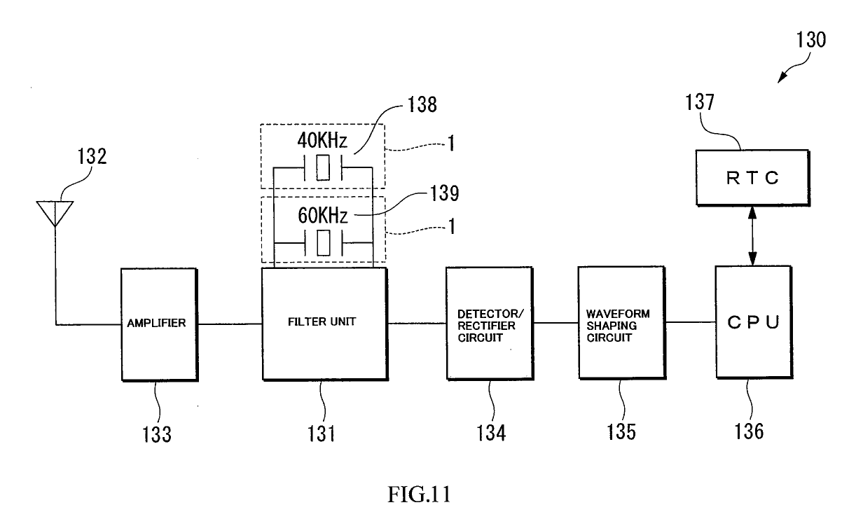

Next, a radio-controlled timepiece according to still another embodiment of the invention will be described with reference to FIG. 11.

FIG. 11 is a view showing the schematic configuration of a radio-controlled timepiece 130.

The radio-controlled timepiece 130 includes the piezoelectric vibrators 1 electrically connected to a filter section 131. The radio-controlled timepiece 130 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionosphere and the land surface, and therefore has a propagation range wide enough to cover the entire area of Japan through the two transmission centers.

As shown in FIG. 11, an antenna 132 of the radio-controlled timepiece 130 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1.

In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134.

Then, the time code is extracted by a waveform shaping circuit 135 and counted by the CPU 136. The CPU 136 reads the information including the current year, the total number of days, the day of the week, the time, and the like. The read information is reflected on an RTC 137, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case of Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 according to the present embodiment includes the piezoelectric vibrator 1 in which the airtightness of the cavity C is secured, it is possible to provide a high-quality radio-controlled timepiece 130 having excellent characteristics and reliability. In addition to this, it is possible to count the time highly accurately and stably over a long period of time.

It should be noted that the technical scope of the present invention is not limited to the embodiments above, and the present invention can be modified in various ways without departing from the spirit of the present invention. That is, specific materials and layer structures exemplified in the embodiments are only examples and can be appropriately changed.

In the above-described embodiments, the bonding material 23 is formed on the front surface 40a of the base substrate wafer 40. However, contrary to this, the bonding material 23 may be formed on the rear surface 50a of the lid substrate wafer 50.

In this case, the bonding material 23 may be formed on only the bonding surface of the rear surface 50a of the lid substrate wafer 50 to be bonded to the base substrate wafer 40 by patterning after the film formation. However, by forming the bonding material 23 on the entire rear surface 50a including the inner surface of the recess portion 3a, the patterning of the bonding material 23 is not necessary, and thus, the manufacturing cost can be decreased.

Furthermore, in the bonding step (S60) described above, a method (a so-called counter electrode method) in which an auxiliary bonding material serving as a positive electrode is disposed on the rear surface 40b of the base substrate wafer 40 and a negative electrode is disposed on the front surface 50b of the lid substrate wafer 50, and a method (a so-called direct electrode method) in which the bonding material 23 is connected to a positive electrode, a negative electrode is disposed on the front surface 50b of the lid substrate wafer 50, and a voltage is directly applied to the bonding material 23 may be used.

When the counter electrode method is used, by applying a voltage between the auxiliary bonding material and the negative electrode at the time of anodic bonding, an anodic bonding reaction occurs between the auxiliary bonding material and the rear surface 40b of the base substrate wafer 40, whereby the bonding material 23 and the rear surface 50a of the lid substrate wafer 50 are anodically bonded. In this way, it is possible to apply a voltage to the entire surface of the bonding material 23 in a more uniform manner and to make the bonding material 23 and the rear surface 50a of the lid substrate wafer 50 reliably anodically bonded.

In contrast, when the direct electrode method is used, since an auxiliary bonding material removal operation after the bonding step, which is necessary in the counter electrode method, is not necessary, it is possible to decrease the number of manufacturing steps and to improve the manufacturing efficiency.

In the present embodiment, a piezoelectric vibrator was manufactured by sealing a piezoelectric vibrating reed in a package using the method of manufacturing a package according to the present invention. However, a device other than the piezoelectric vibrator may be manufactured by sealing an electronic component other than the piezoelectric vibrating reed in a package.

What is claimed is:

1. A method for producing packages for an electronic device, comprising:
(a) defining a plurality of first substrates on a first wafer and a plurality of second substrates on a second wafer, which are layered such that at least some of the first substrates are anodically bonded respectively with at least some of the second substrates;
(b) forming a film on at least one outer surface of a respective at least some of at least one of the first substrates and the second substrates;
(c) laser-abrading a respective at least some of the film-covered surfaces to partially expose the substrate for marking.

2. The method according to claim 1, wherein the film is made of a metal mainly including one of Si, Cr and Ti.

3. The method according to claim 1, wherein the film has a thickness of about 1000 Å to about 3000 Å.

4. The method according to claim 1, wherein laser-abrading a respective at least some of the film-covered surfaces comprises using a laser having a wavelength which is 100% absorbable in the exposed substrate.

5. The method according to claim 1, wherein laser-abrading a respective at least some of the film-covered surfaces comprises using a laser having a wavelength higher than or equal to about 7.5 μm.

6. The method according to claim 1, wherein laser-abrading a respective at least some of the film-covered surfaces comprises using a CO₂ laser.

7. The method according to claim 1, wherein laser-abrading a respective at least some of the film-covered surfaces comprises using a laser having an out power of about 4.5W to about 6W.

8. The method according to claim 1, wherein forming a film comprises forming a film only on an outer top surface of a respective at least some of the first substrates.

9. The method according to claim 1, wherein forming a film comprises forming a film on a respective at least some of the anodically bonded first and second substrate pairs except outer electrodes formed on a bottom surface of the second substrate.

10. The method according to claim 9, wherein laser-abrading a respective at least some of the film-covered surfaces comprises laser-abrading a respective at least some of the bottom surfaces of the second substrates.

11. The method according to claim 1, wherein forming a film comprises forming a film on a respective at least some of the anodically bonded first and second substrates, except a bottom surface of the second substrate which has outer electrodes.

12. The method according to claim 1, further comprising, before Step (b), cutting off a respective at least some of the anodically bonded first and second substrate pairs from the first and second wafers.

13. The method according to claim 12, further comprising, before Step (b), placing at least some of the cut-off first and second substrate pairs separately in recesses formed in a plate, wherein the recesses have a depth such that bonding lines of the first and second substrates pairs placed in the recesses are exposed out of the recesses.

14. The method according to claim 1, further comprising, after Step (b), cutting off a respective at least some of the anodically bonded first and second substrate pairs from the first and second wafers.

15. The method according to claim 1, wherein the electronic device is a piezoelectric reed.

16. A package for an electronic device comprising:
a hermetically closed casing comprising anodically bonded first and second substrates with a cavity formed inside;
a film made of a metal mainly including one of Si, Cr and Ti and having a thickness of about 1000 Å to about 3000 Å which is formed on at least one surface of the first and second substrates, wherein the at least one film-covered surface is laser-abraded to partially expose the substrate for marking; and
an electronic device being secured inside the cavity.

17. The package according to claim 16, wherein the electronic device is a piezoelectric vibrating reed.

18. An oscillator comprising the piezoelectric vibrator defined in claim 17.

19. An electronic device comprising the piezoelectric vibrator defined in claim 17 which is electrically connected to a clock section of the electronic device.

20. A radio-controlled timepiece comprising the piezoelectric vibrator defined in claim 17 which is electrically connected to a filter section of the radio-controlled timepiece.
